(19) United States
(12) Patent Application Publication
(10) Pub. No.: US 2012/0064727 A1
(43) Pub. Date: Mar. 15, 2012

(54) SUBSTRATE TREATMENT EQUIPMENT AND METHOD OF TREATING SUBSTRATE USING THE SAME

(75) Inventors: Jung-min Oh, Incheon (KR); Kun-tack Lee, Suwon-si (KR); Hyo-san Lee, Suwon-si (KR); Young-hoo Kim, Hwaseong-si (KR); Jung-won Lee, Gunpo-si (KR); Sang-won Bae, Incheon (KR); Yong-jhin Cho, Suwon-si (KR)

(73) Assignee: SAMSUNG ELECTRONICS CO., LTD., Suwon-si (KR)

(21) Appl. No.: 13/225,696

(22) Filed: Sep. 6, 2011

(30) Foreign Application Priority Data
Sep. 15, 2010 (KR) 10-2010-0090665

(51) Int. Cl. H01L 21/306; B08B 3/00

(52) U.S. Cl. 438/745; 156/345.23; 134/94.1; 134/26; 257/E21.219

(57) ABSTRACT

Substrate treatment equipment includes a wet treatment apparatus for treating a substrate with a solution (liquid), a drying (treatment) apparatus discrete from the wet treatment apparatus and for drying the substrate using a supercritical fluid, and a transfer device. The substrate is extracted by the transfer device from the wet treatment apparatus after the substrate has been treated and the substrate is transferred by the device while wet to the dry treatment apparatus. To this end, various elements/methods may be used to keep the substrate wet or wet the substrate. In any case, the substrate is prevented from drying naturally, i.e., from air-drying, as the substrate is being transferred from the wet treatment apparatus to the drying apparatus. Thus, equipment and method prevent defects such as water spots and the leaning of fine structures on the substrate.

### PRIORITY STATEMENT

This application claims the benefit of Korean Patent Application No. 10-2010-0090665, filed on Sep. 15, 2010, in the Korean Intellectual Property Office.

### BACKGROUND

The inventive concept relates to the treating of substrates in the manufacturing of semiconductor devices and the like. More particularly, the inventive concept relates to a method of and substrate treatment equipment for treating a substrate wherein the treatment includes a wet process and a process of drying the substrate after it has been wet-processed.

As the magnitudes of design rules for semiconductor devices become smaller, there is a need to form a pattern of fine structures or apertures having large aspect ratios in a substrate, e.g., a wafer. In addition, the manufacturing of semiconductor devices includes treating the substrate, that is, the wafer, in which a pattern of fine structures or apertures having a large aspect ratio have been formed. For example, the substrate must be subjected to a wet process, such as a wet etching or cleaning process, and a drying process. However, the narrow openings of the apertures offer resistance against the treatment, especially, the drying of surfaces delimiting the apertures. Also, the drying of the substrates may leave defects, such as water marks, or cause the fine structures to lean.

Thus, there is a need for a substrate treatment apparatus capable of effectively performing both a wet process and a drying process on a substrate in which a pattern of apertures having large aspect ratios has been formed.

### SUMMARY

According to one aspect of the inventive concept, there is provided substrate treatment equipment including a wet treatment apparatus that treats a substrate with liquid, a drying apparatus discrete from the wet treatment apparatus and that dries the substrate, and a transfer device having liquid retentions means. The drying apparatus includes a source of fluid, and a system that delivers the fluid in a supercritical state to a substrate in the drying apparatus such that the substrate is dried using the supercritical fluid. The transfer device has a working envelope that encompasses the wet treatment apparatus and the drying apparatus and is operative to transfer a substrate that has been treated with liquid by the wet treatment apparatus to the drying apparatus. The liquid retentions means keeps the substrate wet as the substrate is transferred from the wet treatment apparatus to the drying apparatus.

According to another aspect of the inventive concept, there is provided substrate treatment equipment including a wet treatment apparatus, a drying apparatus, and a transfer device comprising a robot having at least one blade dedicated to support a substrate, and liquid retentions means for keeping the substrate wet while it is supported by the at least one blade. The wet treatment apparatus includes a container, a substrate support plate disposed in the container and dedicated to support a substrate, and a liquid dispenser that dispenses liquid into the container such that a substrate supported on the support plate can be treated with the liquid. The drying apparatus includes a container of fluid, a process chamber, a substrate support plate disposed in the process chamber and dedicated to support a substrate, a delivery system that connects the container of fluid to the process chamber and delivers the fluid from the container thereof to the process chamber, and a controller operatively connected to the delivery system and configured to control the pressure and temperature of fluid delivered by the delivery system to the process chamber such that the fluid assumes a supercritical state in the process chamber. The transfer device has a working envelope that encompasses the substrate support plates of the wet treatment apparatus and the drying apparatus so as to be capable of transferring a substrate that has been treated with liquid by the wet treatment apparatus to the drying apparatus while preventing the substrate from drying out.

According to another aspect of the inventive concept, there is provided a method of treating a substrate treatment including treating a surface of a substrate with liquid in a wet treatment apparatus, extracting the substrate from the wet treatment apparatus after it has been treated with the liquid, transferring the extracted substrate to a drying apparatus, and drying the substrate in the drying apparatus using supercritical fluid, wherein the transferring of the extracted substrate comprises keeping the surface of the substrate wet from the time it is extracted from the wet treatment apparatus to the time it is delivered to the drying apparatus.

### BRIEF DESCRIPTION OF THE DRAWINGS

The inventive concept will be more clearly understood from the following detailed description of preferred embodiments thereof taken in conjunction with the accompanying drawings in which:

FIG. 1 is a phase diagram of carbon dioxide (CO₂) that is used in a dry treatment apparatus of an embodiment of substrate treatment equipment according to the inventive concept;

FIG. 2 is a plan view of substrate treatment equipment according to the inventive concept;

FIG. 3 is a flowchart of an embodiment of a substrate treating method according to of the inventive concept.

FIG. 4 is a cross-sectional view of a substrate wet treatment apparatus (SWTA) of the substrate treatment equipment of FIG. 2, according to an embodiment of the inventive concept;

FIG. 5 is a cross-sectional view of another version of a substrate wet treatment apparatus (SWTA) employed in substrate treatment equipment according to the inventive concept;

FIGS. 6 and 7 are schematic diagrams of respective examples of a substrate transfer member of substrate treatment equipment, according to the inventive concept;

FIG. 8 is a graph of vapor pressure with respect to a temperature of a rinsing solution used in a substrate wet treatment apparatus (SWTA) of the substrate treatment equipment according to the inventive concept;

FIGS. 9 and 10 are perspective views of still further examples, respectively, of a substrate transfer member of substrate transfer equipment according to the inventive concept;

FIG. 11 is a set of bottom views of spray nozzles of the transfer members of FIGS. 9 and 10, respectively;

FIGS. 12 and 13 are perspective views of other examples of substrate transfer members of the substrate treatment equipment according to the inventive concept;

FIG. 14 is a cross-sectional view of the transfer members of FIGS. 12 and 13;

FIGS. 15 and 16 are perspective views of still other examples of substrate transfer members of substrate treatment equipment according to the inventive concept;

FIG. 17 is a schematic diagram of a substrate drying treatment apparatus of the substrate treatment equipment of FIG. 2, according to the inventive concept; and

FIG. 18 is a sectional view of a unit that includes the process chamber of the substrate drying treatment apparatus of FIG. 17.

### DETAILED DESCRIPTION OF THE PREFERRED EMBODIMENTS

Various embodiments and examples of embodiments of the inventive concept will be described more fully hereinafter with reference to the accompanying drawings. Note, like numerals are used to designate like elements throughout the drawings.

Terminology used herein for the purpose of describing particular examples or embodiments of the inventive concept is to be taken in the context of the relevant art and is not intended to otherwise convey an idealized or overly formal meaning. That is terms unless otherwise state, such terminology should be given its plain meaning or meaning as understood in the art. For example, the term “supercritical fluid” will be understood as meaning fluid whose temperature and pressure are at or exceed the known critical temperature and critical pressure of that particular fluid. The terms “comprises” or “comprising” when used in this specification specifies the presence of stated features or processes but does not preclude the presence or additional features or processes.

Substrate treatment equipment (STE) according to the inventive concept basically includes a wet treatment apparatus, a drying treatment apparatus that employs supercritical fluid, and a transfer unit for transferring a substrate from the wet treatment apparatus to the drying treatment apparatus. The drying treatment apparatus dries the substrate, which has been treated with solution in the wet treatment apparatus, with the supercritical fluid. An example of the supercritical fluid is carbon dioxide (CO₂) the characteristics of which will be described with reference to the phase diagram of FIG. 1.

In general, temperature and pressure determine the phase—solid, liquid or gas—which a substance assumes. For example, a gaseous substance may liquefy when the pressure of the gas is raised to a certain value while the temperature thereof is kept constant. However, as illustrated in FIG. 1, at or beyond a critical temperature and pressure a fluid assumes a supercritical state. CO₂ has a critical temperature of about 31° C. and a critical pressure of about 73 atm, which are relatively low. Also, CO₂ is non-toxic, non-flammable and is relatively inexpensive.

The minimum temperature and pressure at which the fluid assumes a supercritical state is referred to as the critical point. Supercritical fluids are substances in which liquid and gas phases are indistinguishable. Also, changes in temperature and pressure of supercritical fluid can vary physical properties of the supercritical fluid, such as density, viscosity, diffusion coefficient, and polarity.

In particular, supercritical fluids may have a relatively high solubility, a high diffusion coefficient, low viscosity, and low surface tension similar to that of gases. Therefore, a supercritical fluid may be similar to a gas in that it may readily flow into fine openings. On the other hand, a supercritical fluid may be similar to liquid in terms of its ability to dissolve materials it comes into contact with, i.e. readily acts as a solvent. Thus, watermarks are not formed when a supercritical fluid is used to dry a substrate that has been cleaned or rinsed with a solution, because there is no phase boundary between the gas and liquid phases of the supercritical fluid.

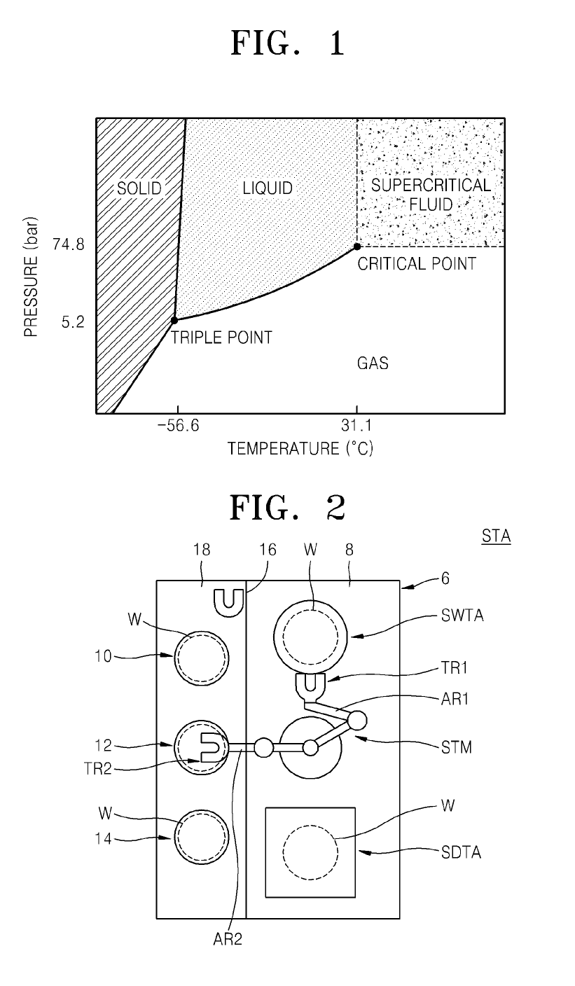

Hereinafter, an embodiment of substrate treatment equipment (STE) according to the inventive concept will be described in more detail with reference to FIG. 2.

FIG. 2 shows the substrate treatment equipment (STE) configured to treat a wafer. However, a wafer, such as a silicon wafer, is just an example of a substrate that may be treated. Another example is a glass substrate and thus, reference character W is used to represent any of various substrates that may be treated. The substrate W may have an aperture therein having a large aspect ratio. Practically speaking, the substrate W will have many such apertures formed in a pattern across its surface.

As mentioned above, the substrate treatment equipment (STE) includes a substrate wet treatment apparatus SWTA for treating the substrate W with solution, a substrate drying treatment apparatus SDTA for drying the substrate W after the wet treatment has been performed, and a substrate transfer means (unit) STM for transferring the substrate W. The substrate wet treatment apparatus SWTA, the substrate drying treatment apparatus SDTA, and the substrate transfer means STM are disposed on a base 8 and are accommodated in a housing 6.

In addition, the substrate treatment equipment STE may include a cassette station 18. The cassette station 18 may also be accommodated in the housing 6. The substrate wet treatment apparatus SWTA and the substrate drying treatment apparatus SDTA are separated from the cassette station 18 by a barrier rib 16 of the housing 6. Although the substrate treatment equipment will be installed in a clean room, the cleanliness inside the housing 6 may be controlled independently of that of the clean room if necessary.

The substrate wet treatment apparatus SWTA treats the substrate with a cleaning or rinsing solution, for example. In the embodiment of FIG. 2, the substrate treatment equipment has only one single substrate wet treatment apparatus SWTA; however, the equipment may have two or more substrate wet treatment apparatuses SWTAs disposed in parallel.

The substrate drying treatment apparatus SDTA treats the substrate W with a supercritical fluid. The substrate W is dried by means of the low viscosity and surface tension of the supercritical fluid. The substrate drying treatment apparatus SDTA is not limited by the kind (properties) of the treatment solution used to perform the wet treatment because the substrate dry treatment apparatus SDTA is an apparatus that is entirely discrete from that of the substrate wet treatment apparatus SWTA.

A cassette having or defining a plurality shelves is loaded on the cassette station 18, and a substrate W is accommodated on the shelves of the cassette. Substrates W are loaded and unloaded onto and from the cassette station 18 by the substrate transfer means STM. In the embodiment of FIG. 2, the cassette station 18 is configured to support three cassettes 10, 12, and 14. The cassettes 10, 12, and 14 are loaded and unloaded onto and from the cassette station 18 by a handling apparatus (not shown). The cassette station 18 may move the cassettes 10, 12, and 14 back and forth into and out of a working envelope of the substrate transfer means (STM). For example, once a substrate W that has been treated has been loaded into the central cassette 12 by the substrate transfer means (STM), the cassette 10 or 14 may be moved to the location formerly occupied by the central cassette 12 whereupon the substrate W accommodated in the cassette 10 or 14 is unloaded by the substrate transfer means (STM) and treated.

That is, the substrate transfer means STM transfers substrates W between the substrate wet treatment apparatus SWTA and the substrate drying treatment apparatus SDTA, and the cassettes 10, 12 and 14 of the cassette station 18. The substrate transfer means STM includes a robot interposed between the substrate wet treatment apparatus SWTA and the substrate drying treatment apparatus SDTA. The robot has articulated horizontal arms AR1 and AR2, and a pair of hands TR1 and TR2 respectively installed at fore-ends of the articulated arms AR1 and AR2. The hands TR1 and TR2 are substrate transfer members (hereinafter, first and second ‘substrate transfer members TR1 and TR2’) each configured to support a substrate W. The horizontal articulated arms AR1 and AR2 are substrate transfer connecting members connected to the substrate transfer members.

The first substrate transfer member TR1 is used to transfer a wet substrate W. That is, the first substrate transfer member TR1 transfers a substrate W from the substrate wet treatment apparatus SWTA to the substrate drying treatment apparatus SDTA. The second substrate transfer member TR2 is used to transfer dry substrates W from the cassettes 10, 12 and 14 of the cassette station 18 to the substrate wet treatment apparatus SWTA, and from the substrate drying treatment apparatus SDTA to the cassettes 10, 12 and 14. A substrate W, which has not yet been treated or which has been dried using the supercritical fluid, can be prevented from being contaminated by moisture left on the substrate transfer means (STM), because the robot uses the first and second substrate transfer members TR1 and TR2 separately as described above. That is, the substrate transfer means has a transfer member that is dedicated for use in handling only wet substrates and a transfer member that is dedicated for use in handling only dry substrates.

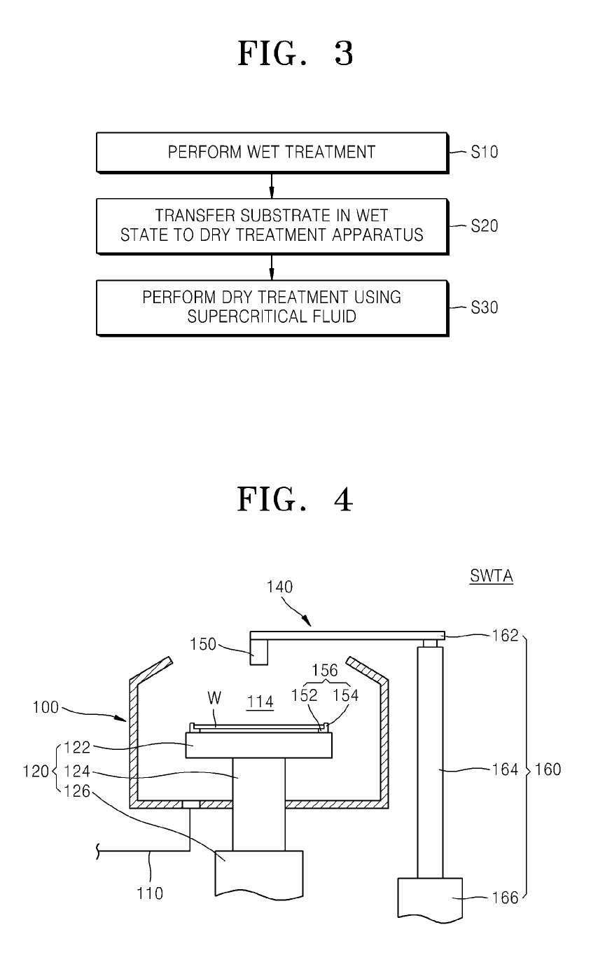

FIG. 3 illustrates the above-described substrate treating method. To reiterate, a wet treatment is performed by extracting a substrate W from a cassette 10, 12 or 14 using the second substrate transfer member TR2 of the substrate transfer means STM, transferring the substrate W to the substrate wet treatment apparatus SWTA, and administering a treatment solution to the substrate W (operation S10). For example, a cleaning treatment is performed by spraying a cleaning solution on the substrate W.

After the wet treatment has been performed, the substrate W may be rinsed with deionized water or isopropyl alcohol (IPA), for example. When IPA is used as the rinsing solution, it can be easily removed by state due to the high solubility of IPA in a supercritical fluid of CO₂. In the case in which deionized water is used as the rinsing solution, a second rinsing treatment may be performed using an organic solvent having better affinity with CO₂ than deionized water, to promote the drying treatment.

The rinsing solution may include a surfactant. When a surfactant is added to the rinsing solution, its vapor pressure is lowered. Thus, the substrate W is prevented from drying naturally when the substrate, which has been treated with solution including a surfactant, is transferred from the wet treatment apparatus to the substrate drying treatment apparatus SDTA. In one example of a method according to the inventive concept, the surfactant is a substance that is highly soluble in CO₂ as well as in the rinsing solution.

The surfactant may include at least one of a trimethylnonanol (TMN) surfactant, a fluorosurfactant with branches, and a surfactant including a fluorinated block copolymer.

An example of the TMN surfactant is TMN-10 available from Union Carbide Corporation and represented by the following formula:

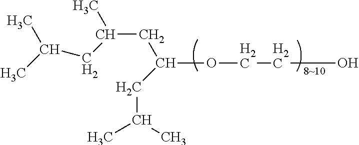

An example of the fluorosurfactant with branches is at least one substance selected from the group consisting of R_{f}CH₂CH₂SCH₂CH₂CO₂Li, (R_{f}CH₂CH₂O)P(O)(ONH₄)₂, (R_{f}CH₂CH₂O)₂P(O)(ONH₄), (R_{f}CH₂CH₂O)P(O)(OH)₂, (R₂CH₂CH₂O)₂P(O)(OH), R_{f}CH₂CH₂O(CH₂CH₂O)ₓH, R_{f}CH₂CH₂O(CHCH₂O)_{y}H, R_{f}CH₂CH₂O(CH₂CH₂O)_{y}H, and R_{f}CH₂CH₂SO₃X(X═H or NH₄). In this case, R_{f} is F(CF₂CF₂)₃₋₈. Such fluorosurfactants are available from E. I. du Pont de Nemours and Company under the trademark ‘ZONYL’, for example, ZONYL-FSA, ZONYL-FSP, ZONYL-FSE, ZONYL-UR, ZONYL-FSJ, ZONYL-TBS, ZONYL-FSN, ZONYL-FSO, or ZONYL-FSD.

An example of the surfactant including the fluorinated block copolymer is one that includes a block copolymer to which at least one of a hydrophilic compound and a hydrophobic fluoro compound is connected, e.g., poly ethylene oxide-block-poly fluorooctyl methacrylate (PEO-block-PFOMA), as represented by the formula below wherein R_{f} is (CH₂—CF₂)₅—CF₃, n is 10-455, and m is 2-100.

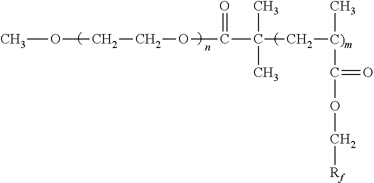

PEO-block-PFOMA is non-ionic, and has excellent stability with respect to acid compounds. In addition, PEO-block-PFOMA may be used successfully to remove an aqueous solution because the number of water molecules of PEO-block-PFOMA bonded to a single surfactant molecule is about 120.

After the rinsing treatment is performed in the substrate wet treatment apparatus SWTA, the substrate W is extracted from the substrate wet treatment apparatus SWTA, and is transferred to the substrate dry treatment apparatus SDTA by the substrate transfer means STM while the surface of the substrate W is still wet (operation S20).

In an example in which the equipment described above in connection with FIG. 2 is used, the substrate W is transferred from the substrate wet treatment apparatus SWTA to the substrate dry treatment apparatus SDTA by the first substrate transfer member TR1 of the substrate transfer means STM. Furthermore, as will be described in more detail later on, the first substrate transfer member TR1 may comprise various components that are useful or assist in the transferring of the substrate W in its wet state to the substrate drying treatment apparatus SDTA.

Next, the substrate is dried by the substrate drying treatment apparatus (SDTA) using the supercritical fluid (operation S30). In this process, the substrate W is loaded into a treatment chamber of the substrate drying treatment apparatus (SDTA), and the temperature of the treatment chamber is lowered to or beyond the critical temperature of the supercritical fluid used to dry the substrate. The drying treatment will be described in more detail below.

After the drying treatment has been performed, the substrate W is extracted from the substrate dry treatment apparatus SDTA. In an example in which the equipment described above with respect to FIG. 2 is used, the substrate W is extracted by the second substrate transfer member TR2 of the substrate transfer means STM. In addition, the substrate W is transferred to the cassette station 18 and loaded into a cassette 10, 12, or 14.

An example of the substrate wet treatment apparatus SWTA of the substrate treatment equipment of FIG. 2, according to the inventive concept, will now be described in more detail with reference to FIG. 4.

The substrate wet treatment apparatus SWTA includes a container 100, a support 120, and a treatment solution dispenser 140. The container 100 has an open top, and the shape of a bowl so as to define a space 114 therein. The container 100 is moveable upward and downward to facilitate the loading and unloading of the substrate W onto and from the support 120. A discharge line 110 for discharging the treatment solution used in a process is coupled to the bottom of the container 100. Cleaning solution discharged through the discharge line 110 may be collected and reused.

The support 120 supports the substrate W during the wet treatment process and includes a supporting plate 122 having an approximately circular shape, a column 124 serving as a rotary drive shaft, and a drive motor 126 having a rotary output. The supporting plate 122 is disposed in the container 100, and the column 124 extends through the center of the bottom of the container 100. The column 124 defines an axis of rotation and couples a rotary output of the motor 126 to the bottom of the supporting plate 122 so that the motor 126 rotates the supporting plate about the axis of rotation.

The support 120 may also include supporting pins 156 spaced apart from each other by predetermined intervals along the outer peripheral portion of the supporting plate 122. In this case, each supporting pin 156 includes a supporting portion 152 that against which a bottom portion of the edge of the substrate W lies, and a protrusion 154 that extends upwards from the supporting portion 152. The protrusion portion 154 prevents the substrate W from being flung off of the supporting plate 122 due to centrifugal force during the wet treatment process while the supporting plate 122 is being rotated by motor 126.

As an alternative to the supporting pins 156, a vacuum line (not shown) may be provided in the supporting plate 122 so that the substrate W may be held to the supporting plate 122 by suction produced by the vacuum in the vacuum line.

The treatment solution dispenser 140 provides the cleaning solution used in the wet treatment of the substrate W. The treatment solution dispenser 140 includes a spray nozzle 150, and a nozzle support 160 for supporting and moving the spray nozzle 150. The nozzle support 160 includes a vertical support arm 164 that extends vertically outside the container 100, and a horizontal support arm 162 that extends from an upper end of the vertical support arm 164 in a horizontal direction. The spray nozzle 150 is coupled to an end of the horizontal support arm 162 and is oriented to spray the treatment solution in a downward direction. The nozzle support 160 also includes a drive motor 166 having a rotary or linear output. The vertical support arm 164 is in the form of a long cylindrical rod, and is rotated around its central axis or is moved in a vertical direction by the drive motor 166. In this way, the spray nozzle 150 can be positioned radially outwardly of the container 100 when the wet process is not being performed to facilitate the loading and unloading of the substrate W.

The dispenser 140 also includes one or more sources of treatment solution, used in the wet treatment of a substrate W, connected to the spray nozzle 150. Again, the treatment solution may include a cleansing solution for removing impurities from the substrate W, and rinsing solution for rinsing the cleansing solution from the substrate W. The cleansing solution may be a solution of hydrofluoric acid (HF), or the like. The rinsing solution may be deionized water, or the like.

The treatment solution dispenser 140 may include a plurality of the spray nozzles 150 and nozzle supports 160 for supporting and moving the nozzles, respectively. Alternatively, the treatment solution dispense 140 may have only one spray nozzle 150, and the spray nozzle 150 may include a plurality of nozzle openings through which solution is dispensed. In this case, the spray nozzle 150 may be fixed in place (directly) above the center of the substrate W during the wet treatment process or the spray nozzle 150 may be positioned above the substrate W and moved radially between a location (directly) over the center of the substrate W and a location (directly) over the outer edge of the substrate W.

In one example of the method of treating a substrate according to the inventive concept in which a single spray nozzle 150 is employed, the spray nozzle is moved radially above the substrate W from the location over the center of the substrate W to the location over the edge of the substrate W while dispensing the cleansing solution onto the substrate W. During a subsequent rinsing treatment, the nozzle 150 is held in place above the center of the substrate W while dispensing rinsing solution onto the substrate. In another example, during the rinsing treatment, the spray nozzle is moved radially from the location over the center of the substrate W to the location over the outer edge of the substrate W.

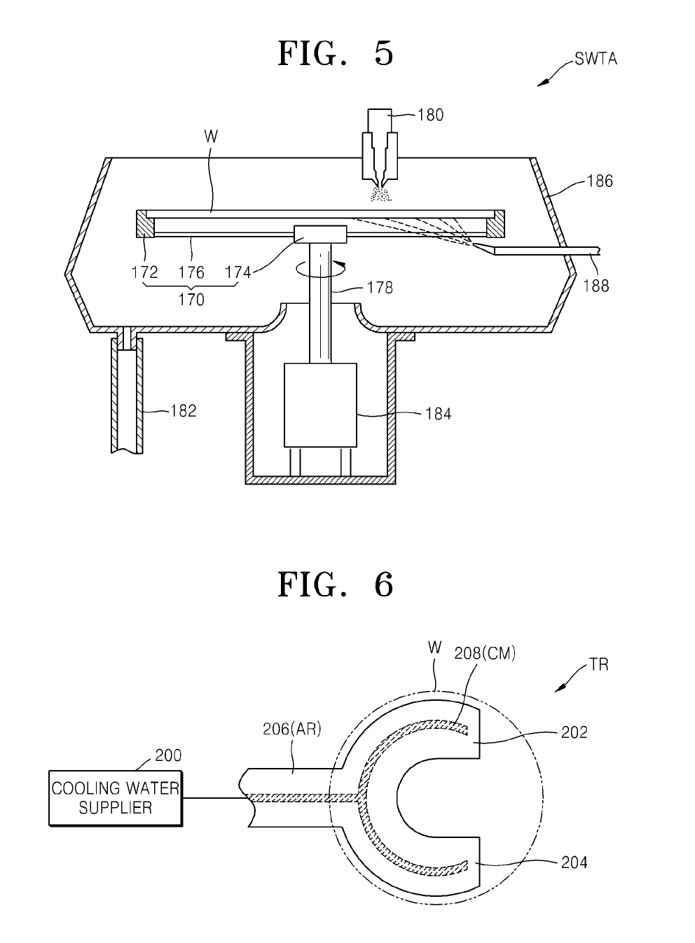

Another example of the substrate wet treatment apparatus SWTA of the substrate treatment equipment STE of FIG. 2, according to the inventive concept, will be described with reference to FIG. 5.

The substrate wet treatment apparatus SWTA of this example includes a supporting member 170, a rotary drive motor 184, a column 178 serving as a rotary drive shaft for transferring the rotary output of the motor 184 to the supporting member 170, spray nozzles 180 and 188, and a container 186. The supporting member 170 includes a hub 174 connected to the column 178, a circular ring 172 for supporting the substrate W, and a plurality of spokes 176 connecting the circular ring 172 and the hub 174 to each other. The supporting member 170, though, is not limited to the above-described structure, but may have various other components configured to support the substrate W.

Similar to the SWTA of FIG. 4, the container 186 may have the shape of a bowl so as to confine and collect the cleaning solution or the rinsing solution that is dispensed onto the surface of the substrate W and is flung from the surface due to rotation of the substrate W. The column 178 extends through the center of the bottom of the container 186. The container 186 may also be supported so as to be moveable upward and downward to facilitate the loading and unloading of the substrate W. Also, a discharge line (pipe) 182 for discharging the solution may be coupled to the bottom of the container 186. Cleaning solution discharged through the discharging line 182 may be collected and reused.

The spray nozzle 180 administers the cleaning solution or the rinsing solution to an upper surface of the substrate W. A second spray nozzle 188 administers the cleaning solution to a lower surface of the substrate W. As illustrated in FIG. 5, the second spray nozzle 188 may extend through a side wall of the container 186.

The cleaning solution may be deionized water, a mixture of HF and deionized water, a mixture of ammonium hydroxide (NH₄OH), hydrogen peroxide (H₂O₂) and deionized water, a mixture of ammonium fluoride (NH₄F), HF and deionized water, a mixture of phosphoric acid and deionized water, or the like. The rinsing solution may be deionized water or IPA.

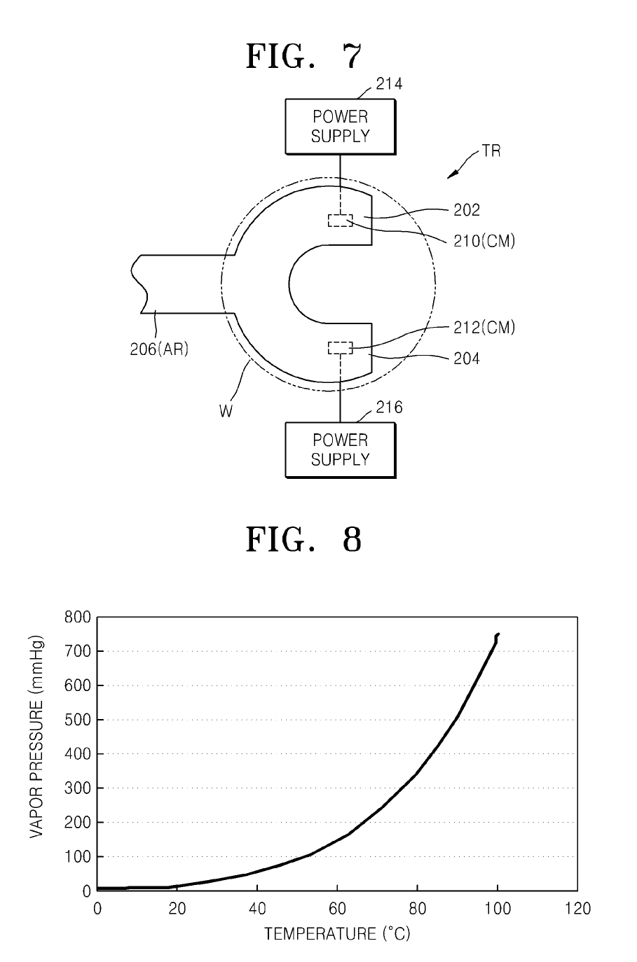

Examples of a substrate transfer member TR of the substrate transfer means STM of the substrate treatment equipment (STE) of FIG. 2 will now be described with reference to FIGS. 6 and 7, respectively.

Referring to FIGS. 6 and 7, each example of the substrate transfer member TR includes at least one blade for supporting the substrate W, a substrate transfer connection arm AR that supports the at least one blade, and a cooling mechanism CM that prevents the substrate W from drying naturally as it is being transferred by the TR. In the illustrated examples, the TR includes first and second blades 202 and 204, having a gap therebetween, for supporting the substrate W. However, the TR may have only a single blade. The temperature of the TR may be controlled by the cooling mechanism CM to be 25° C. or less with the above-stated aim of preventing the substrate from drying. Reference will be made hereinafter to the examples in which the TR has the first and second blades 202 and 204.

Supporting pins (not shown) for supporting the substrate W may be installed on the first and second blades 202 and 204. In addition, a vacuum line (not shown) for creating suction on the substrate W may be installed in the first and second blades 202 and 204.

In the example of FIG. 6, the cooling mechanism CM is a cooling line 208 that extends in the first and second blades 202 and 204. The cooling line 208 may also extend through the substrate transfer connection arm AR, as shown in the figure. A cooling water supply 200, including a source of cold water, is connected to the cooling line 208. The cooling water supply 200 circulates cold water through the line 208 and hence, through the first and second blades 202 and 204.

In the example of FIG. 7, the cooling mechanism CM is a pair of piezoelectric devices 210 and 212 disposed on bottom surfaces of the first and second blades 202 and 204 or in the first and second blades 202 and 204, respectively. Power supplies 214 and 216 are connected to the piezoelectric devices 210 and 212, respectively for supplying power to the piezoelectric devices 210 and 212. The Cooling mechanism CM may also be a pair of Peltier devices.

FIG. 8 is a graph of vapor pressure with respect to temperature of a rinsing solution, namely deionized water or IPA, used in the substrate wet treatment apparatus SWTA of the substrate treatment equipment STE of FIG. 2, according to the inventive concept. As illustrated in the graph, the vapor pressure of the rinsing solution decreases as the temperature thereof is decreased. Thus, the cooling mechanisms CM as described with reference to FIGS. 6 and 7 can prevent rinsing solution on the substrate W from evaporating, i.e., can prevent the substrate W from drying, as the substrate W is transferred from the substrate wet treatment apparatus SWTA to the substrate drying treatment apparatus SDTA.

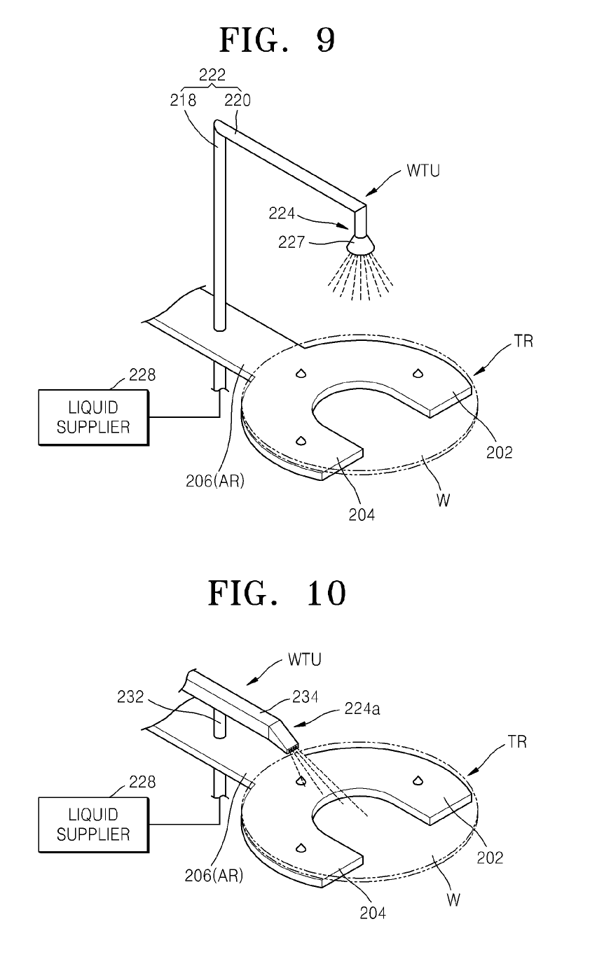

Other examples of a substrate transfer member TR of the substrate transfer means STM will now be described with reference to FIGS. 9 and 10.

Each substrate transfer member TR is the same as those of FIGS. 6 and 7 except that each substrate transfer member TR of FIGS. 9 and 10 includes a wet transfer unit WTU instead of a cooling mechanism CM. Also, these figures show the previously referred to supporting pins 203 for supporting the substrate W on the first and second blades 202 and 204. Although three such supporting pins 203 are shown, four or more supporting pins may be provided. Also, in this case, a vacuum line (not shown) for creating suction on the substrate W may be installed in the first and second blades 202 and 204. The other features of the substrate transfer members TR which are similar to those described with reference to FIGS. 6 and 7 will not be described in detail any further.

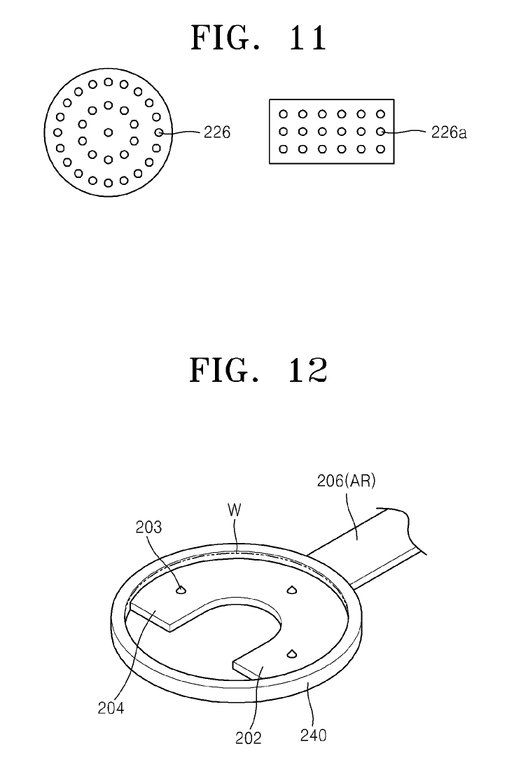

In the examples of FIGS. 9 and 10, the wet transfer unit WTU is mounted to the substrate transfer connection member AR. In the example of FIG. 9, the wet transfer unit WTU has a support 222 extending upright on the substrate transfer connection member AR, and a spraying device 224 mounted to the supporter 222 for spraying a drying-prevention liquid onto the substrate W supported by the blades 202 and 204 of the substrate transfer member TR. The spraying device 224 may include a showerhead 227 whose spray nozzles 226 are arranged as illustrated on the left in FIG. 11.

The support 222 may include a vertical support member 218 that extends perpendicular to the substrate transfer connection member AR, and a horizontal support member 220 that extends parallel to the substrate transfer connection member AR. In this case, the shower head 227 of the spraying device 224 is installed at an end of the horizontal support member 220 and so as to be located over the center of a substrate W supported by the blades 202 and 204. The support 222 may be connected to a liquid supplier 228 which comprises a source of the drying-prevention liquid. That is, the support 222 may be piping connecting the source of the drying-prevention liquid to the shower head 227. The drying-prevention liquid may be the same as the rinsing solution. Thus, the liquid supplier 228 may provide deionized water or IPA to the showerhead 227.

The shower head 227 sprays the drying-prevention liquid onto the substrate W uniformly. To this end, the shower head 227 may be supported so as to rotate in a plane parallel to the substrate W. In addition, the spray nozzles 2226 of the shower head 227 may individually rotate in a plane parallel to the substrate W.

In the example of FIG. 10, the wet transfer unit WTU includes a vertical support member 232 extending upright on (perpendicular to) the substrate transfer connection arm AR, a horizontal support member 234 connected to the vertical support member 232, and a spraying device 224a at the end of the horizontal support member 234. The spraying device 224a includes spray nozzles 226a arranged in the pattern shown on the right in FIG. 11. The spraying device 224a is located adjacent a lateral portion of the blades 202 and 204, over a location along the outer edge of a substrate W supported by the blades 202 and 204, and is oriented to spray the drying-prevention liquid towards the center of the substrate W.

Still other examples of a substrate transfer member TR of the substrate transfer means STM will be described with reference to FIGS. 12, 13 and 14.

The substrate transfer member TR of FIGS. 12 and 13 is the same as any of the substrate transfer members TR of FIGS. 6, 7, and 9 through 11 except that the substrate transfer members TR of FIGS. 12 and 13 include a guide 240 instead of a cooling mechanism CM or wet transfer unit WTU. The other features of the substrate transfer members TR which are similar to those described previously will not be described in detail any further.

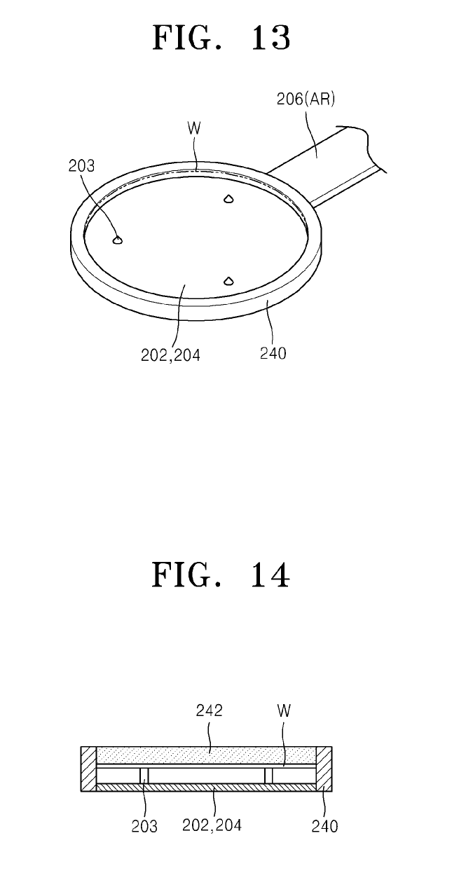

The guide 240 extends upright along the periphery of the blade or blades 202 and 204 of the substrate transfer member TR. In particular, the guide 240 is annular. FIG. 12 shows an example in which the substrate transfer member TR has first and second (i.e., two) blades 202 and 204 whereas FIG. 13 shows an example in which the substrate transfer member TR has only a single blade. In either case, the guide 240 encircles a substrate W supported on the blade or blades 202 and 204, as illustrated in FIG. 14.

In this case, rinsing solution 242 may be left on the substrate W as the substrate transfer means STM transfers the substrate from the substrate wet treatment apparatus SWTA to the substrate drying treatment apparatus SDTA so as not to be wasted and such that the substrate does not dry out. To this end, the guide may not only include an annular wall but also an annular seal provided along the interior of such an annular wall to lessen the chance that the rinsing solution 242 will drain off of the upper surface of the substrate W.

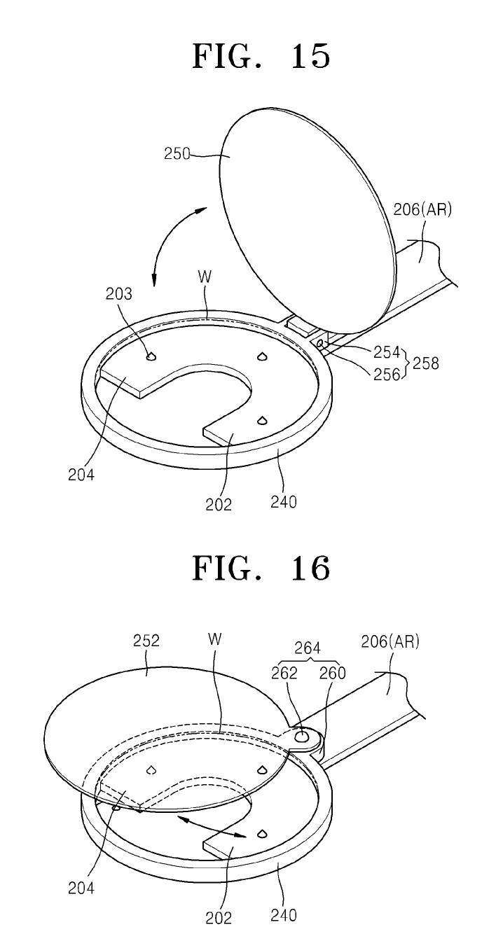

FIGS. 15 and 16 show another feature of a substrate transfer member TR of the substrate transfer means STM. Specifically, the substrate transfer members TR of FIGS. 15 and 16 each have a cap 250 or 252 disposed on the guide 240. The cap 250 or 252 may be mounted to the substrate transfer connection arm AR or the guide 240.

In the example of FIG. 15, the cap 250 is mounted to a connection block unit 258 interposed between the substrate transfer connection member AR and the guide 240. The connection block unit 258 may be mounted on only the substrate transfer connection arm AR, however. The connection block unit 258 has a first set of protrusions or hub 254 protruding from the guide 240, and a connector 256 rotatably supported by the first protrusions 254 and connected to the cap 250. In particular, the connector 256 is supported to be rotatable about a horizontal axis. Thus, the cap 250 may be swung vertically (in the direction of the double-headed arrow) between a first closed position at which it rests on the guide 240 and covers the substrate W and a second open position (shown) which allows the substrate W to be loaded onto and unloaded from the substrate transfer member TR.

In the example of FIG. 16, the cap 252 is connected to a connection block unit 264 also interposed between the substrate transfer connection arm AR and the guide 240 but which may be mounted on only the substrate transfer connection arm AR. The connection block unit 264 may includes a protrusion or hub 260 protruding from the guide 240, and a connector 262 rotatably supported by the protrusion 260 and connected to the cap 252. In particular, the connector 262 is supported to be rotatable about a vertical axis. Thus, the cap 252 may be swung horizontally (in the direction of the double-headed arrow) between a first closed position at which it rests on the guide 240 and covers the substrate W and a second open position which allows the substrate W to be loaded onto and unloaded from the substrate transfer member TR.

The caps 250 and 252, in particular, can prevent rinsing solution 242 (see FIG. 14) from evaporating and/or being blown off of the upper surface of the substrate W as the substrate transfer means STM transfers the substrate W from the substrate wet treatment apparatus SWTA to the substrate drying treatment apparatus SDTA. Thus, the substrate W can be prevented from drying naturally before it reaches the substrate drying treatment apparatus SDTA.

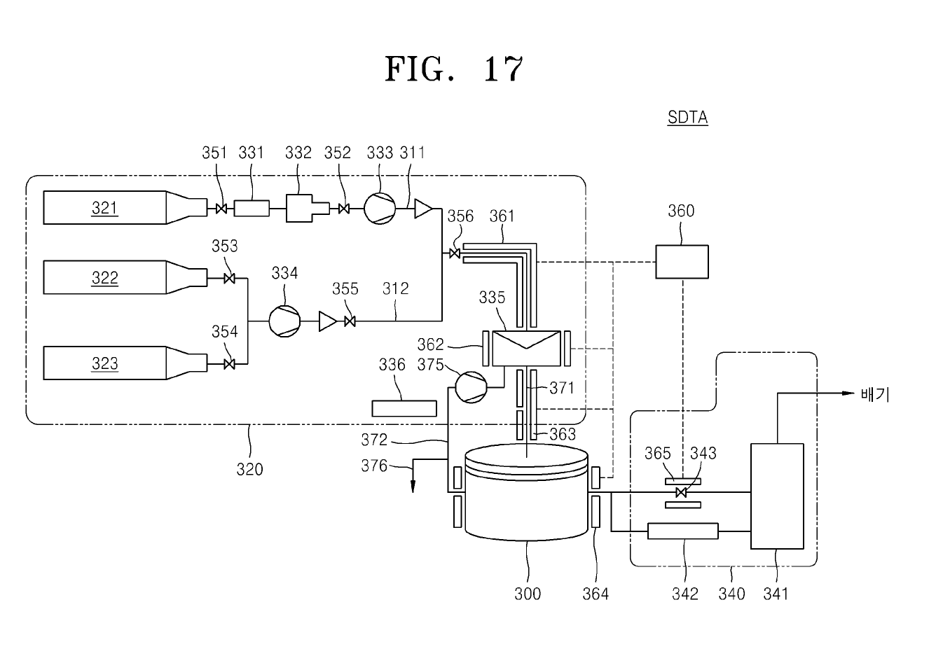

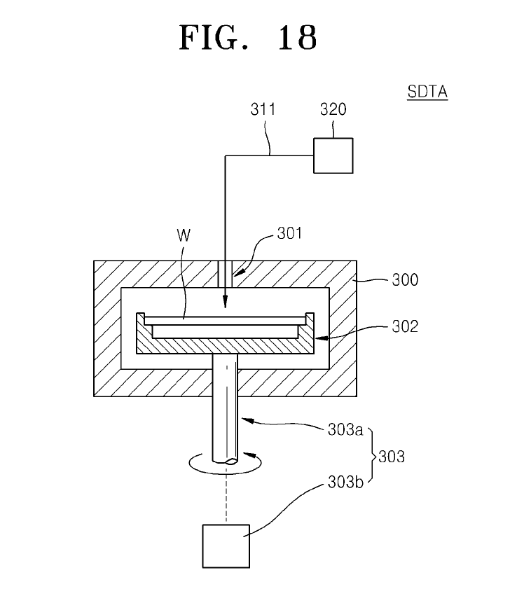

An example of the substrate dry treatment apparatus SDTA of the substrate treatment equipment STE of FIG. 2, according to the inventive concept, will now be described in detail with reference to FIG. 17.

The substrate dry treatment apparatus SDTA has a process chamber 300, a supply unit 320, and a discharge section 340. The substrate W is dried in the process chamber 300. The supply unit 320 supplies the supercritical fluid to the process chamber 300. The discharge section 340 discharges the supercritical fluid from the process chamber 300. The supercritical fluid may be CO₂ the properties of which were described with reference to FIG. 1.

The supply unit 320 of this example includes a first container 321 of solvent (e.g., CO₂) used to dry the substrate W, and may also include second and third containers 322 and 323 of a co-solvent. The co-solvent may be the rinsing solution and surfactant, examples of which were also given above.

A booster 331 for providing a constant amount of the solvent (by regulating the flow rate), and a cooler 332 for pressurizing the solvent are disposed in-line between the first container 321 and the process chamber 300. A first pressure pump 333 for increasing the pressure of the solvent to its critical pressure or beyond is installed in-line between the cooler 332 and the process chamber 300. A mixer 335 for mixing the solvent and the co-solvent with each other is installed in-line between the first pressure pump 333 and the process chamber 300. The booster 331, the cooler 332, and the first pressure pump 333 may thus be disposed along a first pipe 311 connecting the first container 321 and the mixer 335 to each other. The mixer 335 can also finely adjust the amount of the supercritical fluid introduced in the process chamber 300.

The second and third containers 322 and 323 are connected to the mixer 335 through a second pipe 312. A second pressure pump 334 for increasing the pressure of the solvent is installed in the second pipe 312.

Valves 351 through 356 for controlling the amounts of solvent and co-solvent may be installed in the piping (e.g., the first pipe 311 and the second pipe 312) connecting the process chamber 300 and the first through third containers 321 through 323 to each other. In addition, a controller (not shown) may be provided to control the operations of the valves 351 through 356, the booster 331, the cooler 332, the first and second pressure pumps 333 and 334, and the mixer 335. The discharge section 340 may also be controlled by the controller.

The discharge section 340 of this example includes a separator 341 for separating harmful materials discharged from the process chamber 300. A discharging valve 343 is disposed in-line between the separator 341 and the process chamber 300. A rupture disk 342 for preventing the pressurized solvent from being suddenly discharged from the process chamber 300 is connected to the process chamber 300. All or some of the above-described components may be electronically controlled by the controller.

In order to maintain a supercritical state of the solvent, the pressure and temperature of the solvent needs to be maintained at or beyond those of the critical point, as described above. Thus, this example of the SDTA further includes a control system 360 (temperature sensor, a pressure sensor, a temperature controller, and a pressure controller) for monitoring and controlling the temperature and pressure of the fluid. First to fifth temperature control jackets 361 through 365 controlled by the temperature controller of this system 360 may be installed around a section of the piping leading to the mixer 335, the mixer 335, the piping between the process chamber 300 and the mixer 335, the process chamber 300, and the discharging valve 343.

The piping connecting the mixer 335 and the process chamber 300 may be configured to circulate the supercritical fluid therebetween. In this case, the piping includes a first circulation pipe 371 for providing the supercritical fluid prepared by the mixer 335 to the process chamber 300, and a second circulation pipe 372 for transmitting the supercritical fluid used in the process chamber 300 to the mixer 335. In order to circulate the supercritical fluid, a circulation pump 375 is installed in the circulation piping. In this respect, the circulation pump 375 may be disposed in either the first circulation pipe 371 or the second circulation pipe 372. Reference numeral 336 designates an auxiliary or assistant pump to provide co-solvent to the first circulation pipe 371.

An elbow 376 for discharging a portion of the used supercritical fluid may be connected to the second circulation pipe 372. Use of the elbow 376 allows for supercritical fluid of high purity to be returned to the mixer 335. Thus, a drying process may be performed using supercritical fluid of a substantially uniform purity, without substantial changes in pressure occurring in the process chamber 300.

An example of a unit which includes process chamber 300 of the substrate drying treatment apparatus SDTA of FIG. 17, and of the process that occurs therein, will now be described in further detail with reference to FIG. 18.

The process chamber 300 has a relatively thick chamber wall that can withstand a high pressure but has a closeable opening (not shown) that allows the substrate W to pass therethrough into and out of the chamber 300. A substrate loading support plate 302 is disposed in the chamber 300. The substrate support plate 302 is connected to a rotary driving mechanism 303 including a shaft 303a and a motor whose rotary output is connected to the shaft so that the substrate support plate 302 can be rotated by the motor 303b. In another example of the unit, the substrate support plate 302 is fixed in the chamber 300 so as to be stationary.

The supercritical fluid, whose temperature and pressure are adjusted by the supply unit 320, is introduced into the process chamber 300 through the pipe 311, such that the atmosphere in the process chamber 300 is changed to a supercritical state (for example, a temperature and pressure 35° C. and 9 MPa). The supercritical state is maintained for a predetermined period of time during which the substrate W is dried using the supercritical fluid. Then the pressure of the process chamber may be lowered to the critical point of the supercritical fluid or beyond. In this case, the resulting gas may be discharged out of the process chamber.

If desired, the drying may be promoted by rotating the substrate W. For instance, a fairly long period of time is required to completely remove deionized water from the substrate W by dissolving all of the deionized water in the supercritical fluid. However, rotating the substrate W during the drying process causes even tiny amounts of deionized water left on the substrate W to dissolve in the supercritical fluid due to the centrifugal force on the water. Thus, the substrate W may be effectively dried in a relatively short amount of time.

According to an aspect of the inventive concept as described above, a substrate is wet processed, e.g., etched or cleaned, and then dried using a supercritical fluid. Thus, the substrate can be dried thoroughly.

Also, according to an aspect of the inventive concept as described above, the substrate transfer means STM for transferring the substrate W from the substrate wet treatment apparatus SWTA to the substrate drying treatment apparatus SDTA prevents the substrate from drying naturally along the way. That is, the substrate W arrives still wet at the substrate drying treatment apparatus SDTA. Thus, a substrate wet treated and then dried will not have defects such as water marks or fine structures which are leaning.

Finally, embodiments of the inventive concept have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiments described above but by the following claims.

What is claimed is:

1. Substrate treatment equipment comprising:
a wet treatment apparatus that treats a substrate with liquid;
a drying apparatus discrete from the wet treatment apparatus and that dries the substrate, the drying apparatus including a source of fluid, and a system that delivers the fluid in a supercritical state to a substrate in the drying apparatus such that the substrate is dried using the supercritical fluid; and
a transfer device having a working envelope that encompasses the wet treatment apparatus and the drying apparatus and operative to transfer a substrate that has been treated with liquid by the wet treatment apparatus to the drying apparatus,
wherein the transfer device has liquid retentions means for keeping the substrate wet as the substrate is transferred from the wet treatment apparatus to the drying apparatus.

2. The substrate treatment equipment of claim 1, wherein the transfer device comprises a substrate transfer member having at least one blade dedicated to support the substrate, and
the liquid retention means comprises a cooling device that cools the substrate on the at least one blade of the substrate transfer member.

3. The substrate treatment equipment of claim 2, wherein the cooling device includes a cooling line extending along the at least one blade.

4. The substrate treatment equipment of claim 2, wherein the cooling device comprises a piezoelectric device integrated with the at least one blade.

5. The substrate treatment equipment of claim 1, wherein the transfer device comprises a substrate transfer member having at least one blade dedicated to support the substrate, and
the liquid retention means comprises a wet transfer unit operative to dispense liquid onto the substrate supported by the at least one blade.

6. The substrate treatment equipment of claim 5, wherein the wet transfer unit comprises a support integral with the substrate transfer member, and at least one spray nozzle mounted to the support.

7. The substrate treatment equipment of claim 1, wherein the transfer device comprises a substrate transfer member having at least one blade dedicated to support the substrate, and
the liquid retention means comprises a guide extending around the at least one blade.

8. The substrate treatment equipment of claim 7, wherein the liquid retention means further comprises a cap disposed on the guide so as to cover the substrate supported by the at least one blade.

9. The substrate treatment equipment of claim 1, wherein the wet treatment apparatus comprises a surfactant dispenser that dispenses a surfactant onto the substrate in the wet treatment apparatus.

10. Substrate treatment equipment comprising:
a wet treatment apparatus including a container, a substrate support plate disposed in the container and dedicated to support a substrate, and a liquid dispenser that dispenses liquid into the container such that a substrate supported on the support plate can be treated with the liquid;
a drying apparatus including a container of fluid, a process chamber, a substrate support plate disposed in the process chamber and dedicated to support a substrate, a delivery system that connects the container of fluid to the process chamber and delivers the fluid from the container thereof to the process chamber, and a controller operatively connected to the delivery system and configured to control the pressure and temperature of fluid delivered by the delivery system to the process chamber such that the fluid assumes a supercritical state in the process chamber; and
a transfer device having a working envelope that encompasses the substrate support plates of the wet treatment apparatus and the drying apparatus so as to be capable of transferring a substrate that has been treated with liquid by the wet treatment apparatus to the drying apparatus,
wherein the transfer device comprises a robot having at least one blade dedicated to support a substrate, and liquid retentions means for keeping the substrate wet while it is supported by the at least one blade.

11. The substrate treatment equipment of claim 10, wherein the liquid retention means comprises a cooling device that cools the substrate supported by the at least one blade.

12. The substrate treatment equipment of claim 11, wherein the cooling device includes a cooling line extending along the at least one blade.

13. The substrate treatment equipment of claim 10, wherein the cooling device comprises a piezoelectric device integrated with the at least one blade.

14. The substrate treatment equipment of claim 10, wherein the robot has an arm from which the at least one blade extends, and the liquid retention means comprises at least one spray nozzle mounted to the arm.

15. The substrate treatment equipment of claim 10, wherein the liquid retention means comprises a guide extending around the at least one blade.

16. The substrate treatment equipment of claim 15, wherein the liquid retention means further comprises a cap disposed on the guide so as to cover the substrate supported by the at least one blade.

17. A substrate treatment method comprising:
treating a surface of a substrate with liquid in a wet treatment apparatus;
extracting the substrate from the wet treatment apparatus after it has been treated with the liquid, and transferring the extracted substrate to a drying apparatus, wherein the transferring of the extracted substrate comprises keeping the surface of the substrate wet from the time it is extracted from the wet treatment apparatus to the time it is delivered to the drying apparatus; and
drying the substrate in the drying apparatus using supercritical fluid.

18. The substrate treatment method of claim 17, wherein the transferring of the extracted substrate includes introducing, onto the surface of the substrate after the substrate has been extracted from the wet treatment apparatus, a drying-prevention liquid that keeps the surface of the substrate wet up until at least the time the substrate is delivered to the drying apparatus.

19. The substrate treatment method of claim 17, wherein the transferring of the extracted substrate includes cooling the substrate after the substrate has been extracted from the wet treatment apparatus to keep liquid on the surface of the substrate from evaporating and thereby keep the surface of the substrate wet up until at least the time the substrate is delivered to the drying apparatus.

20. The substrate treatment method of claim 17, wherein the transferring of the extracted substrate comprises blocking the outer peripheral edge of the upper surface of the substrate with a barrier such that liquid on the upper surface of the substrate can not escape therefrom.
